(19) United States
(12) Patent Application Publication
(10) Pub. No.: US 2005/0111507 A1
(43) Pub. Date: May 26, 2005

(54) Surface-emitting semiconductor laser and method of fabricating the same

(75) Inventors: Nobuaki Ueki, Kanagawa (JP); Fumio Koyama, Kanagawa (JP)

Correspondence Address: OLIFF & BERRIDGE, PLC, P.O. BOX 19928, ALEXANDRIA, VA, 22320, US

(73) Assignees: FUJI XEROX CO., LTD., Tokyo (JP); Fumio KOYAMA, Yokohama-shi (JP)

(21) Appl. No.: 10/882,268

(22) Filed: Jul. 2, 2004

(30) Foreign Application Priority Data
Nov. 25, 2003 (JP) 2003-393580

(51) Int. Cl. H01S 5/00

(52) U.S. Cl. 372/50; 372/45; 372/46

(57) ABSTRACT

A surface-emitting semiconductor laser includes a first reflection layer formed on a substrate; an active layer formed on the first reflection layer; a second reflection layer formed on the active region; an electrode that has an aperture that defines a light emission range and is provided on the second reflection layer so that an uppermost layer of the second reflection layer is exposed through the aperture; and a third reflection layer that is provided on the electrode so as to cover the aperture. The third reflection layer includes a conductive film that electrically contacts the uppermost layer of the second reflection layer.

### BACKGROUND OF THE INVENTION

1. Field of the Invention

The present invention relates to a surface-emitting semiconductor laser used as a light source in optical information processing and high-speed optical communications, and a method of fabricating such a surface-emitting semiconductor laser.

2. Description of the Related Art

In the technical field of the optical communication and the optical recording, an interest to a surface-emitting semiconductor laser (Vertical-cavity Surface-emitting Laser Diode, hereinafter referred to as VCSEL) has been increased in these years.

VCSEL has technical advantages that a threshold current is small, an optical spot of a circular shape can be easily obtained, and an evaluation at a wafer state and two dimensional array of the light source can be achieved. “Small volume of the active region” causes the low threshold current while there is a trade off that a device resistance is dozens of to hundreds of Ohms, which is higher than that of an edge-emitting semiconductor laser, and that obtaining a high optical output(not less than 10 mW) by itself is difficult.

The optical communication using an optical fiber has applied to a data transmission for a relatively middle or long distance (from several to dozens of kilometers). Typically, a combination of a single mode optical fiber and a distributed-feedback type (hereinafter referred to as DFB) laser is used. The DFB laser is oscillated at a wavelength range such as 1.31 micron meter band or 1.55 micron meter band, which is a low dispersion or loss in the optical fiber. They are mainly used for so-called “carrier” who participates in core network, and the production volume is not large compared with consumer products. It makes the price expensive. Furthermore, the system in itself has many problems of reducing a cost since it needs to control a device temperature and to take time for alignment optical axes to the optical fiber and the laser.

These days, ADSL and CATV become widely used for families, and a high capacity data transmission, which is ten times to hundred times compared with the past, has been achieved. Increasing of the Internet user in future will be expected. Additionally, a demand for a high speed and a high capacity of data transmission will be enhanced and it is promising that many families will utilize the optical fiber in some day.

However, the combination of the single mode type of optical fiber and DFB laser for the middle/long distance, for example a few meters to dozens of meters of data transmission between home and an telegraph pole, is diseconomy. For the short distance communication (several to hundreds of meter), using a low cost optical fiber such as a multi-mode type of silica fiber or a plastic optical fiber(POF) is economical. Thus, the light source used for the multi-mode type of the optical fiber is required to be an affordable and not to need a particular an optical system and a driving system. VCSEL would be an option since it can satisfy with all above requirements.

VCSEL available at the present market is structurally classified into an ion-planting type and a selective-oxidation type. If the high speed response is required in the optical communication in future, latter type would be mainstream. VCSEL of this type has a strong effectiveness for optical confinement and provides excellent electro-optical characteristics of a high efficiency and a low threshold current because a part of a semiconductor multiple layer reflecting mirror adjacent to an active region is selectively oxidized to form a refractive-index type waveguide therein. Additionally a modulation bandwidth (3 dB down cut-off frequency) reaches at a few giga-hertz even though a bias current is a few milliampere, and the response shows an excellent high speed modulation characteristic.

The leading role of the local area network (LAN) of an indoor network is Ethernet® and its data transmission rate starts at dozens of mega bit per second (Mbps) and has made a progress at hundreds of mega bit per second. Recently the rate of 1 giga bit per second (Gbps) has appeared and rate would get to hundreds Gbps in near future. Until 1 Gbps, an electric wiring using a twist pair cable can be applied, but it is considered that an optical network would take over it more than 1 Gbps because of a limit in the view of noise tolerance.

There is an aggressive trend to adopt VCSEL in the light source used for the optical network in the Ethernet of 10 Gbps and a development has been advanced. As explained above, there is no problem of the modulation at several GHz, but any measure is necessary to improve the response characteristics over 10 GHz.

A theoretical review of the modulation bandwidth for the semiconductor laser is disclosed in “Semiconductor Laser”, Kenichi Iga, Ohmsha, 1990”. This paper explains that a relaxation-oscillation-frequency (fᵣ), which is a target of an improvement of the modulation bandwidth, is conducted by formula (2) with a rate equation.

$${f}_{r} = \frac{1}{2 π} \sqrt{\frac{ξ {G}^{′} {P}_{out}}{{η}_{d} {h}_{{ω}_{o}} {V}_{m}}} \qquad ( 1 )$$

where ε is optical confining coefficient, G′ is a derivation gain coefficient, Pₒᵤₜ is an optical output, η_{d} is an external derivation quantum efficiency, Vₘ is a mode volume of a resonator, h is a plank constant. It is understood that the relaxation-oscillation-frequency fᵣ increases in proportion to a square root of the optical output. Frequently, the injection current (bias current) is increased to improve the response and increase the optical output.

However, it is well known that the increased injection current increases the current density (the amount of current per unit area) in the light emission region and affects the lifetime of the device. This may be avoided by widening the diameter of the current confining area and increasing the effective current density. It can be seen from equation (1) mentioned above that the increased diameter of the current confining area increases the mode volume Vm of the resonator and does not substantially improve the response characteristics.

As another point of view, the increased optical power may exceed a safety standard called eye safe. According to JIS C 6802 that prescribes the safety standard of laser products, Class 1 (in which safety is ensured when light is continuously incident to an eye for 30,000 seconds (about eight hours)) is defined for the 850 nm wavelength lasers is defined as being equal to or lower than 0.78 mW. If the Class 1 standard may not be met, it is required to incorporate an additional instrument in the system or module, such as a monitor device for monitoring and controlling the optical output, or a shield plate for shutting out a leakage emission.

Here, fᵣ can also be described in a different expression as follows:

$$\begin{matrix}{f}_{r} = \frac{1}{2 π} \sqrt{\frac{ξ {G}^{′} {S}_{0}}{{τ}_{p}}} & ( 2 ) \\ {S}_{0} = \frac{{τ}_{p} ( {I}_{0} - {I}_{th} )}{e {V}_{a}} & ( 3 )\end{matrix}$$

where G′ is a differential gain coefficient, ip is the photon life time, ξ is the optical confinement coefficient, So is the stationary solution of the photon density for the injection current Io. It can be seen from the above that the response can be improved as the threshold current decreases for the identical amount of injection current.

It is therefore conceivable to narrow the diameter of the light emission region (reduce the volume of the active region) to reduce the threshold current and the amount of injection current whereby fᵣ can be raised.

By the way, the 3 dB down cut-off frequency (f_{3dB}), which is an indication that describes the modulation bandwidth, is represented as formula (4) if inductive reactance is negligible:

$${f}_{3 d B} = \frac{1}{2 π C R} \qquad ( 4 )$$

That is, the frequency response depends on the CR time constant. Since narrowing the size of the active region necessarily increases the device resistance, the cutoff frequency becomes lower, and the improvement in the frequency response is cancelled. The increased device resistance is undesirable in terms of impedance matching with driver.

Taking the above into consideration, the inventors studied a method of realizing a VCSEL that has improved response and simultaneously satisfies the eye-safe-based safety standard, which have a difficulty in simultaneous implementation by the current technique. Then, we concluded that it is effective to reduce the threshold current without changing the diameter of the active region. This may be achieved by increasing the reflectance of the resonator to the limit level at which the optical output can be extracted.

There are two methods for improving the reflectance in VCSEL with a distributed Bragg reflector, one of which is to increase the difference in the refractive index between mirror layers having different refractive index values, the other being to increase the number of periods of the mirror.

U.S. Pat. No. 5,428,634 discloses a VCSEL capable of emitting visible light having two structures on the second (upper) mirror. If the second mirror is formed by pairs of AlAs/AlGaAs or InAlP/InAlGaP, the second mirror will have a relatively large resistance value. In order to avoid this problem, the above-mentioned patent discloses a first structure that consists of a smaller number of pairs of semiconductor layers and a second structure that is provided on the first structure and is formed by a dielectric layer. The use of the two structures reduces the resistance of the second mirror. A contact with an electrode is made at the interface between the uppermost semiconductor layer and the dielectric layers.

Generally, VCSEL employs a mirror having a reflectance of more than 99% in order to obtain laser oscillation at room temperature. In design, there is not considerable difficulty in obtaining such a VCSEL device. However, in practice, the VCSEL devices have deviations from the designed specification due to the composition of materials and controllability of film thickness. It is unusual to practically obtain the resonators that have the designed specification. If the reflectance is lower than 99%, laser oscillation will not easily be obtained. In contrast, the reflectance is higher than 99.9%, only an extremely low laser power will be obtained. In the worst, the VCSEL does not oscillate.

As described above, it is very difficult to definitely determine the reflectance of the resonator of VCSEL and to achieve a reflectance increased to the limit level at which the optical output can be obtained in a single process of forming the reflection film.

That is, in the conventional VCSEL structure or fabrication process, the actual reflectance cannot be known until the fabrication process is practically completed. The reflectance values are roughly checked, which are fed back to the fabrication process in order to adjust the number of mirror pair.

The above-mentioned U.S. patent does not describe or suggest fine control of the mirror reflectance in VCSEL.

### SUMMARY OF THE INVENTION

The present invention has been made in view of the above circumstances and provides a surface-emitting semiconductor laser and a method of fabricating the same.

According to an aspect of the present invention, a surface-emitting semiconductor laser comprising a first reflection layer formed on a substrate; an active layer formed on the first reflection layer; a second reflection layer formed on the active region; an electrode that has an aperture that defines a light emission range and is provided on the second reflection layer so that an uppermost layer of the second reflection layer is exposed through the aperture; and a third reflection layer that is provided on the electrode so as to cover the aperture, the third reflection layer including a conductive film that electrically contacts the uppermost layer of the second reflection layer.

According to another aspect of the present invention, there is provided a method of fabricating a surface-emitting semiconductor laser comprising the steps of: forming, on a substrate, a first reflection layer, a second reflection layer, an active region interposed between the first and second reflection layers, and at least one current confining layer interposed between the first and second reflection layers; forming electrodes via which current is injected to the active region; checking an operating characteristic by injecting the current to the active region; and forming, after checking the operation characteristic, an additional reflection layer on the second reflection layer. It is possible to adjust the reflectance so that the maximum optical output of the device is less than that defined by the eye safe standard. Thus, the monitoring device and shield plate are no longer needed.

The selective oxidization technique is used to form the current confining layer. Thus, it is possible to avoid extreme reduction in the differential quantum efficiency and stabilize oscillation. The size of the conductive region of the current confining layer (which size is practically the diameter of a circular shape) may be set smaller than that of the electrode (which is practically the diameter of a cylindrical shape). It is thus possible to obtain the single-mode oscillation while restraining multi-mode oscillations.

A conductive film of the third reflection layer may electrically contact the uppermost layer of the second reflection layer. In this case, the conductive film may be used as part of the contact electrode. This makes it possible to vertically inject current to the emission region and to thus improve the oscillation efficiency.

The third reflection film may include at least one conductive film, so that the third reflection film can be used as part of the contact electrode and as a passivation film before and after the process.

The third reflection layer is provided on the second reflection layer so that the reflectance of the resonator can finely be adjusted. It is thus possible to avoid an extremely low optical output or no oscillation. It is also possible to stabilize oscillation and realize modulation performance over tens of GHz while meeting the eye safe standard.

### BRIEF DESCRIPTION OF THE DRAWINGS

Preferred embodiments of the present invention will be described in detail based on the following figures, wherein:

FIG. 1A is a sectional view of a surface-emitting semiconductor laser according to a first embodiment of the present invention;

FIG. 1B is a schematic perspective view of the laser shown in FIG. 1A;

FIG. 2A is a sectional view of a surface-emitting semiconductor laser according to a second embodiment of the present invention;

FIG. 2B is a schematic perspective view of the laser shown in FIG. 2A;

FIGS. 3A, 3B and 3C explain the functions of an additional reflection film employed in the present invention;

FIGS. 4A, 4B and 4C are sectional views that show a process of fabricating the surface-emitting semiconductor laser according to the first embodiment of the present invention; and

FIGS. 5A, 5B and 5C are sectional views that show a process of fabricating the surface-emitting semiconductor laser according to the second embodiment of the present invention.

### DESCRIPTION OF THE PREFERRED EMBODIMENTS

A description will now be given of embodiments of the present invention. VCSEL devices according to the embodiments have a mesa (or post) formed on a semiconductor substrate in which a current confining layer is formed by the selective oxidization technique and laser light is emitted from the top of the mesa.

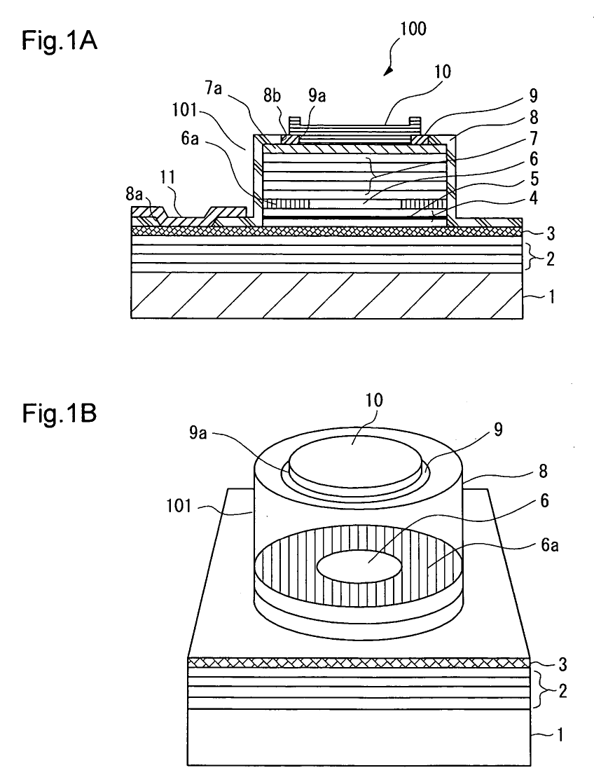

FIGS. 1A and 1B show a VCSEL according to a first embodiment of the present invention. More particularly, FIG. 1A is a sectional view of a VCSEL 100, and FIG. 1B is a schematically perspective view thereof. Referring to these figures, on a semiconductor substrate 1, laminated are a lower multilayer reflection film 2, a contact layer 3, a spacer layer 4, an active layer 5, an AlAs layer 6 and an upper multilayer reflection film 7. The film may be referred to layer throughout. The AlAs layer 6 includes an oxide region 6a formed by oxidizing a peripheral portion of the AlAs layer 6, and serves as a current confining layer. The upper multilayer reflection film 7 includes a p-type contact layer 7a arranged in the uppermost layer. A mesa (or post structure) 101 having a cylindrical shape is formed so as to extend from the contact layer 7a to the spacer layer 4. The sidewall and the peripheral portion of the mesa 101 is covered with an insulating film 8.

A contact hole (aperture) 8b is formed on the top of the insulating film 8. A p-side top electrode 9 having a doughnut shape is formed and positioned within the aperture 8b. An aperture 9a located in the center of the top electrode 9 defines a laser emission region via which laser light can be emitted from the mesa 110. The top electrode 9 is electrically connected to the contact layer 7a, via which current necessary for laser oscillation is injected. An interconnection line (not shown for the sake of simplicity) extends from the top electrode 9 to an electrode pad.

An additional reflection film 10 having a circular shape is provided on the top electrode 9 so as to cover the aperture 9a of the top electrode 9. An n-side bottom electrode 11 is provided on the bottom of the mesa 101 and is electrically connected to the contact layer 3 via a contact hole (window) 8a formed in the insulating film 8.

An inner section surrounded by the oxide region 6a corresponds to light emitting region in the plane parallel to the main surface of the semiconductor substrate 1. The additional reflection film 10 that covers the aperture 9a of the top electrode 9 is formed so as to overlap with a part of the light emitting region in a direction perpendicular to the main surface of the semiconductor substrate 1. The additional reflection film 10 is a multilayer film that includes electrically conductive films. The additional reflection film 10 reflects part of laser light emitted from the active layer 5, and allows the rest of light to pass and go out of the device.

With the above-mentioned structure, it becomes possible to check the operation of the device and evaluate the performance thereof in advance of forming the additional reflection film 10. It is therefore possible to select, on the basis of the results of check and evaluation, the materials, the thickness, and the number of layers of the additional reflection film 10 and to adjust the final reflectance and make a decision on what level the maximum light output can be reduced to.

The additional reflection film 10 is formed by the multilayer film structure including at least the conductive film that electrically contacts the contact layer 7a (the uppermost layer of the upper multilayer reflection film 7). This makes an electrical contact between the conductive layer and the semiconductor layer within the range defined by the aperture 9a of the ring-shaped top electrode 9. It is desirable that the contact between the additional reflection film 10 and the upper multilayer reflection film 7 is an ohmic contact. Even if the Schottky contact is made between the films 7 and 10, these films are at an identical potential, and current can be uniformly injected to the active layer 5 as long as an electrical contact between the top electrode 9 and the additional reflection film 10 are made. This results in effective current injection to the device and improves the device performance.

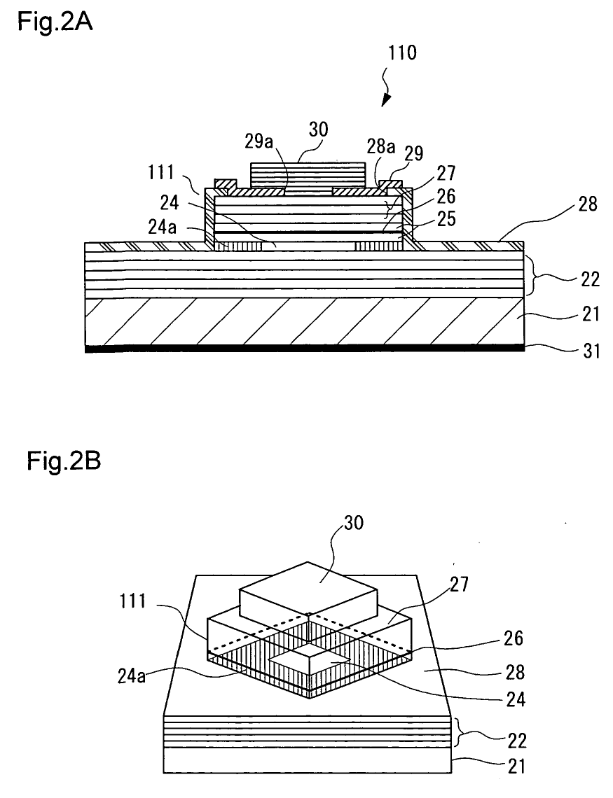

FIGS. 2A and 2B show a VCSEL according to a second embodiment of the present invention. More particularly, FIG. 2A is a sectional view of a VCSEL 110, and FIG. 2B is a schematically perspective view thereof. The VCSEL 110 has a semiconductor substrate 21, on which laminated are a lower multilayer reflection film 22, an Al_{0.98}Ga_{0.22}As layer 24, an oxide region 24b around the Al_{0.98}Ga_{0.22}As layer 24, a spacer layer 25, an active layer 26, an upper multilayer reflection film 27, an interlayer insulating film 28, a p-side upper electrode 29, an additional reflection film 30, and an n-side backside electrode 31 formed on the bottom of the semiconductor substrate 21.

A mesa or post 111 has a rectangular column shape and extends from the upper multilayer reflection film 27 to the oxide region 24b (current confining layer). The sidewall and the bottom of the mesa 111 is covered with the interlayer insulating film 28. The upper electrode 29 having a ring shape is formed on the upper surface of the upper multilayer reflection film 27 in order to inject current to the current confining region via a contact hole 28a formed on the top of the interlayer insulating film 28. The current confining region is defined by the oxide region 24a and the Al_{0.98}Ga_{0.22}As layer 24, which is located inside the oxide region 24a and is the remainder of the oxidizing process. The additional reflection fil 30 is provided so as to cover an aperture 29a formed in the upper electrode 29.

The inside region surrounded by the oxide region 24a corresponds to the light emission region of the device in the plane horizontal to the main surface of the substrate 21. The additional reflection film 20 that covers the aperture 29a f the upper electrodes 29 is formed so as to overlap at least a part of the light emission region in the direction perpendicular to the main surface of the substrate 21. The additional reflection film 30 is a multilayer film that includes at least one electrically conductive film. The additional reflection film 30 reflects part of laser light emitted from the active layer, and the remainder is emitted to the outside of the device through the additional reflection film 30.

In the above-mentioned structure, it is possible to check the device operation and evaluate the device performance in advance of forming the additional reflection film 30. It is therefore possible to select, on the basis of the results of check and evaluation, the materials, the thickness, and the number of layers of the additional reflection film 30 and to adjust the final reflectance and make a decision on what level the maximum light output can be reduced to.

When the lowermost layer of the additional reflection film 30 is an electrically conductive film, a contact between the conductive layer and the semiconductor layer can be made within the aperture 29a of the ring-shaped upper electrode 29. When an electrical contact is made between the upper electrode 29 and the additional reflection film 30, they are of an identical potential, so that current can be uniformly injected to the active layer. Thus, efficient current injection can be achieved and the device performance can be improved.

A dielectric film may be made except the lowermost layer, and may be used as a passivation film before and after the process.

The Al_{0.98}Ga_{0.02}As layer 24 in the current confinement region may have a size smaller than the size of the aperture 29a of the upper electrode 29. In the example shown in FIGS. 2A and 2B, the mesa has a rectangular column shape, and the Al_{0.98}Ga_{0.02}As layer 24 has a size corresponding to the rectangle. With the above structure, it is possible to restrain high-order modes out of the multi modes and obtain the single mode. When the mesa 111 has a cylindrical shape, the Al_{0.98}Ga_{0.02}As layer 24 has a corresponding cylindrical shape and the aperture 29a of the upper electrode 29 has a corresponding circular shape. The high-order modes can be restrained by setting the diameter of the aperture 29a smaller than that of the cylindrical Al_{0.98}Ga_{0.02}As layer 24.

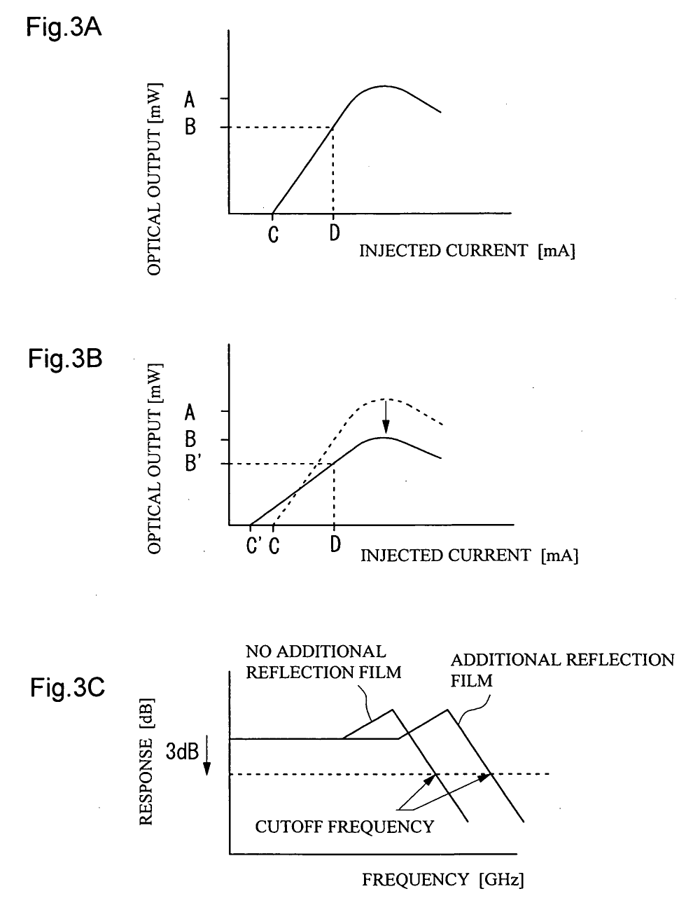

FIGS. 3A, 3B and 3C show optical outputs for cases with and without the additional reflection film. More particularly, FIG. 3A shows an optical output of the conventional VCSEL without the additional reflection film. FIG. 3B shows an optical output of the VCSEL with the additional reflection film according to the present embodiment of the invention. The vertical axes in FIGS. 3A and 3B denote the optical output [mW], and the horizontal axes denote the magnitude of the injection current [mA]. FIG. 3C show frequency responses of the VCSELs shown in FIGS. 3A and 3B. In FIG. 3C, the vertical axis denotes the response [dB], and the horizontal axis denotes the frequency [GHz].

In FIG. 3A, a letter “A” is an optical output that conforms to the eye safe standard, “B” is an optical output corresponding to a magnitude D of injection current necessary to obtain a given-level modulation characteristic, and “C” is a threshold current value. In FIG. 3B, a letter “B′” is the magnitude D of injection current necessary to obtain the given-level modulation characteristic without the additional reflection film. A letter “C′” is a reduced threshold current value obtained with the additional reflection film. In FIG. 3B, the broken line is the same as the solid line in FIG. 3A.

It is possible to easily restrain the maximum value of the optical output to a level equal to or lower than the eye safe standard level and reduce the threshold current value of the laser device. Thus, as shown in FIG. 3C, the cutoff frequency with the additional reflection film becomes higher for the identical drive current, so that the modulation range can be widened without increasing the drive current value.

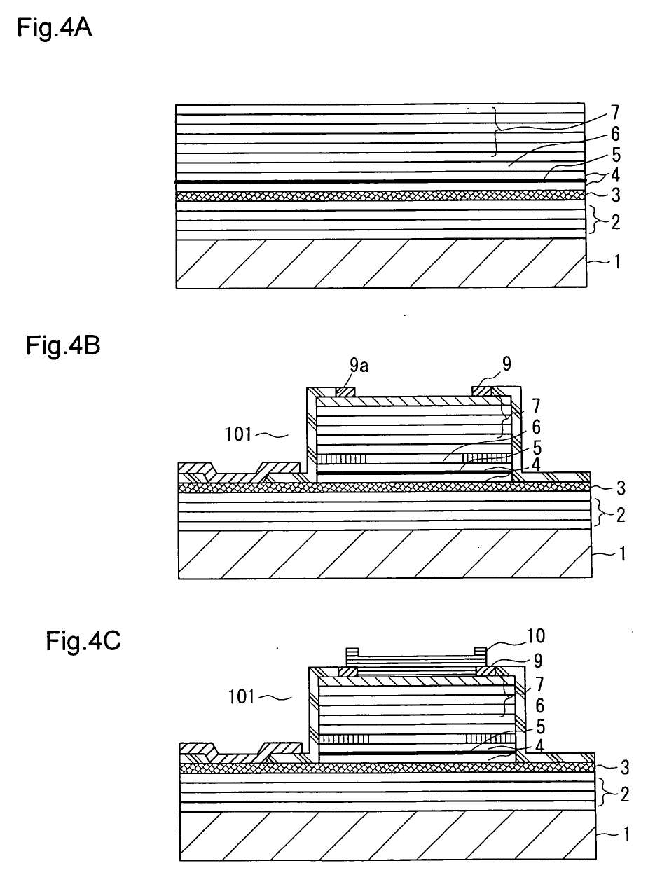

A more detailed description will now be given of the VCSEL devices according to the first and second embodiments of the present invention. FIGS. 4A through 4C are sectional views of the VCSEL shown in FIGS. 1A and 1B observed in the fabrication process. As shown in FIG. 4A, on the (100) surface of the semi-insulating GaAs substrate 1, laminated are the lower multilayer reflection film 2, the n-type GaInP contact layer 3, the undoped Al_{0.4}Ga_{0.6}As spacer layer 4, the active layer 5, the p-type AlAs layer 6, and the upper multilayer reflection film 7 in that order. This process employs MOCVD (Metal Organic Chemical Vapor Deposition). The lower multilayer reflection film 2 is a laminate of undoped Al_{0.8}Ga_{0.2}As layers and undoped Al_{0.1}Ga_{0.9}As layers that are alternately laminated one by one. The active layer 5 is a laminate of a barrier layer and a quantum well layer. The barrier layer includes an undoped Al_{0.2}Ga_{0.8}As layer. The quantum well layer includes an undoped GaAs layer. The upper multilayer reflection film 7 is a laminate of p-type Al_{0.8}Ga_{0.2}As layers and Al_{0.1}Ga_{0.9}As layers that are alternately laminated one by one.

Each of the layers that form the laminate of the lower multilayer reflection film 2 has a thickness equal to λ/4nᵣ wherein λ is the oscillation frequency, and nᵣ is the optical refractive index in the medium. Two layers having different Al composition ratios are alternatively laminated to 36.5 periods.

The contact layer 3 that is the n-type GaInP is provided in order to make a contact with the n-side electrode 11, which will be described later. The contact layer 3 is, for example, 10 to 20 nm thick, and forms a part of the lower multilayer reflection film 2. Thus, the 0.5 period of the lower multilayer reflection film 2 is occupied by the contact layer 3. The carrier concentration after doping with silicon as the n-type impurity is 3×10¹⁸ cm⁻³.

The active layer 5 is designed as follows. A laminate is located in the center of the spacer layer 4 made of an undoped Al_{0.4}Ga_{0.6}As layer. This laminate is composed of a quantum well active layer of an undoped GaAs layer having a thickness of 8 nm and a barrier layer of an undoped Al_{0.2}Ga0.8As layer having a thickness of 5 nm alternately laminated (the outer layer is the barrier layer). The spacer layer including the quantum well active layers and the barrier layers has a thickness equal to an integer multiple of λ/4nᵣ. Light having a wavelength of 850 nm is emitted from the active layer 5 thus formed.

The upper multilayer reflection film 7 is a laminate having layers of p-type Al_{0.8}Ga_{0.2}As layers and p-type Al_{0.1}Ga_{0.9}As layers that are alternately laminated one by one. Each layer of the upper multilayer reflection film 7 has a thickness equal to an integer multiple of λ/4nᵣ like the lower multilayer reflection film 2. Two layers having different Al composition ratios are alternatively laminated to 22 periods, which include the AlAs layer 6 and the GaAs layer that forms the uppermost layer as will be described later. The AlAs layer 6 may not be required so that materials used to form the film thickness λ/4nᵣ are AlAs. A problem such as increase of loss due to optical scattering may occur if the AlAs layer is thicker than necessary. With the above in mind, the AlAs layer 6 employed in the present embodiment is set equal to 30 nm, and the remainder is an Al_{0.9}Ga_{0.1}As layer. The carrier concentration after doping with carbon as the p-type impurity is 4×10¹⁸ cm⁻³.

The number of periods (layers) of the upper multilayer reflection film 7 is smaller than that of the lower multilayer reflection film 2 in order to obtain oscillation light from the upper side due to the difference in the refractive index. In order to reduce the series resistance of the device, an intermediate layer may be interposed between the Al_{0.8}Ga_{0.2}As layer and the Al_{0.1}Ga_{0.9}As layer in the upper multilayer reflection film 7 so that the intermediate layer has an intermediate Al composition ratio therebetween.

The uppermost layer of the upper multilayer reflection film 7 is a p-type GaAs layer that is 20 nm thick in order to improve the contact with the p-side electrode 9. The carrier concentration after doping with zinc (Zn) as the p-type impurity is 1×10¹⁹ cm⁻³.

Next, the laser substrate is brought out from the growth chamber and a mask pattern of SiO₂ is formed using the photoresist process. Using SiO₂ as the mask, the etching is done for forming the cylindrical post or mesa as shown in FIG. 4B. The upper multiple layer reflection film 7, the AlAs layer 6 and the spacer layer 4 including the active layer 5 are etched by the anisotropic etching. For example, a H₂SO₄+H₂O₂+H₂O is used as an etchant. The selective etching ratio for AlGaAs and GaInP is at least 10 times. Making use of such selective etching ratio, the etching can be stopped precisely when etching reaches the GaInP layer 3. This is because the etching rate reduces quickly. In this way, the side of the AlAs layer 6 over the spacer layer 4 is exposed. The AlAs layer 6 will be degenerated in the following oxidation process, and it forms the oxidized region 6a at the peripheral portion, which functions to confine the current and light.

The substrate is then subjected to a steam atmosphere containing nitrogen as a carrier gas (flow rate: 2 little/min) at 350° C. for 30 minuets. The AlAs layer 6 forming a part of the upper multiple layer reflecting mirror 7 is oxidized. The oxidation rate of the AlAs layer 6 is significantly faster than that of Al_{0.8}Ga_{0.2}As and Al_{0.1}Ga_{0.9}As, which also forms a part of the upper multiple layer reflecting mirror 7. As shown in FIG. 4B, oxidation starts from the side of the AlAs layer 6 placed just above the active layer 5 of the post 101. Eventually, the oxidized region 6a that reflects the post shape is formed. The oxidized region 6a serves as the current confining portion because of its reduced conductivity. Simultaneously, the oxidized region 6a serves as an optical confinement region because it has an optical refractive index (˜1.6) as low as half the refractive indexes of the peripheral semiconductor layers. The remainder of the AlAs layer 6 that has not been oxidized serves as a current injection part.

An insulating film is provided on the side and upper exposed surfaces of the post and the substrate. Then, the contact holes 8a and 8b are formed in the insulating film, so that the interlayer insulating film 8 can be completed.

Subsequently, as shown in FIG. 1A, the n-side electrode 11 is formed on the bottom of the post in order to make an electrical contact with the GaInP contact layer 3 via the contact hole 8a. A pattern of the p-side electrode 9 is formed on the top of the post so as to make an electrical contact with the p-type GaAs layer that is the uppermost layer of the upper multilayer reflection film 7. The aperture 9a for emission of light is formed in the center of the p-side electrode 9. A lead interconnection is provided to the p-side electrode 9 although it is not illustrated.

At this stage, the operation of the device can be checked. Current is injected to the device via the top electrode 9 or the bottom electrode 11 so that the oscillation threshold current and maximum optical power of the device can be measured. Based on data thus obtained, as shown in FIG. 4C, a multilayer film is deposited in which indium oxide (ITO) layers doped with tin (Sn) and zinc oxide (ZnO) layers doped with aluminum, which are alternately laminated one by one. Then, the device is subjected to a liftoff process, so that the additional reflection film 10 can be formed in the center of the substrate and on the top of the post. Each of the additional reflection film 10 may be equal to λ/4nᵣ like the lower multilayer reflection film 2. The additional reflection film 10 is provided so as to cover the aperture 9a formed in the center of the p-side electrode 9 for emission of light.

ITO has a refractive index of about 2.2, and ZnO has a refractive index of about 1.8. There is not a great difference in the refractive index between these materials. However, the additional reflection film 10 is used for final adjustment of the refractive index. This can be achieved by only 5 to 10 periods in many cases. For example, when the upper multilayer reflection film 7 has a reflectance of 0.99 (with regard to the wavelength of laser light oscillated), it can be finely adjusted to 0.995 by using the additional reflection film 10. Thus, the reflectance of the resonator can be controlled and the threshold current can be reduced, so that VCSEL 100 that meets the eye safe standard can be produced.

In the present embodiment, the semiconductor (GaInP) layer that contacts the n-side electrode is used as the contact layer 3. The contact layer is formed inside the resonator defined by the upper and lower multilayer reflection films. This is called intra-cavity structure. The lower multilayer reflection film 2 does not form a current path, and a flow of the carrier occurs between the top electrode 9 and the contact layer 3.

The contact layer 3 should be made of a material that lattice-matches the GaAs substrate because the device is formed using epitaxial growth. In order to cause the contact layer 3 to definitely stop etching, GaInP is employed in the present embodiment. A material containing Al such as AlGaInP may be used to merely achieve lattice match. However, GaInP may be superior to AlGaInP because it is thermally stable and is capable of easily making an ohmic contact.

In the structure mentioned above, a single process epitaxially grows the layers up to the upper multilayer reflection film 7. Then, the layers above the contact layer 3 (these layers are the upper multilayer reflection film 7, the AlAs layer 6, the active layer 5 and the spacer layer 4) are removed by etching so that the emission region remains in order to form the bottom electrode 11. In this process, the layers above the contact layer 3 can be selectively etched with respect to the contact layer 3 at an etching ratio of 1:10 or higher. Thus, the surface of the contact layer 3 can easily be exposed with high precision.

The contact layer 3 of GaInP disposed in the vertical direction in the vicinity of the active layer 5 is optically transparent for laser light having a wavelength equal to or longer than 700 nm. In this wavelength range, laser light is not absorbed, and an optimal material can thus be selected.

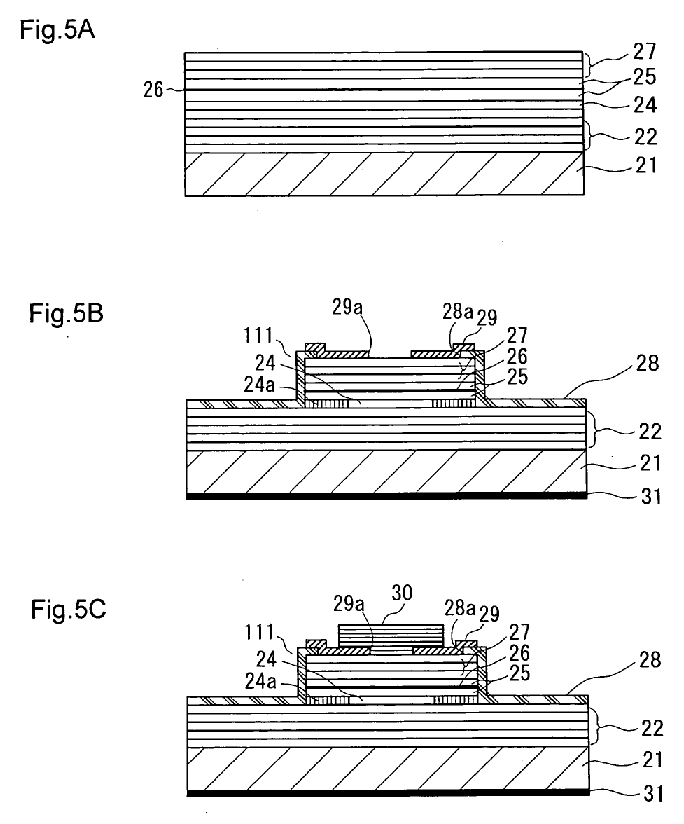

FIGS. 5A through 5C show a process of fabricating the VCSEL according to the second embodiment of the present invention shown in FIGS. 2A and 2B. As shown in FIG. 5A, on the (100) surface of the GaAs substrate 21, laminated are the lower multilayer reflection film 22, the n-type GaInP contact layer 3, the n-type Al_{0.98}Ga_{0.02}As layer 24, the undoped Al_{0.4}Ga_{0.6}As spacer layer 25, the active layer 26, the upper multilayer reflection film 27 in that order. This process employs MOCVD. The lower multilayer reflection film 22 is a laminate of n-type Al_{0.8}Ga_{0.2}As layers and n-type Al_{0.1}Ga_{0.9}As layers that are alternately laminated one by one. The active layer 26 is a laminate of a barrier layer and a quantum well layer. The barrier layer includes an undoped Al_{0.2}Ga_{0.8}As layer. The quantum well layer includes an undoped GaAs layer. The upper multilayer reflection film 27 is a laminate of p-type Al_{0.8}Ga_{0.2}As layers and Al_{0.1}Ga_{0.9}As layers that are alternately laminated one by one. A description will be omitted of the same structure of the device shown in FIGS. 5A through 5C as that of the device shown in FIGS. 4A through 4C.

The lower multilayer reflection film 22 includes a laminate of n-type Al_{0.8}Ga_{0.2}As layers and n-type Al_{0.1}Ga_{0.9}As layers, each of which is λ/4nᵣ thick where λ is the oscillation frequency, and nᵣ is the optical refractive index in the medium. Two layers having different Al composition ratios are alternatively laminated to 36.5 periods. This number of periods includes the Al_{0.98}Ga_{0.02}As layer 24 that is the uppermost layer. The carrier concentration after doping with silicon as the n-type impurity is 5×10¹⁸ cm⁻³. The 30 nm thickness of the n-type Al_{0.98}Ga_{0.02}As layer 24 is insufficient to realize λ/4nᵣ. An Al_{0.1}Ga_{0.9}As layer is used to make up for the insufficient length.

The p-type upper multilayer reflection film 27 is a laminate of p-type Al_{0.8}Ga_{0.2}As layers and p-type Al_{0.1}Ga_{0.9}As layers. Each of the layers is λ/4nᵣ thick like the lower multilayer reflection film 22. Two layers having different Al composition ratios are alternately laminated to 17 periods. The carrier concentration after doping with carbon as the p-type impurity is 4×10¹⁸ cm⁻³.

The laser substrate is brought out from the growth chamber, and the laminate is formed into the post or mesa 111 having a rectangular column shape. Etching is controlled to a depth in which at least the side surface of the Al_{0.98}Ga_{0.02}As layer 24 that is the uppermost layer of the lower multilayer reflection film 22 is exposed.

Then, the upper electrode 29 having a ring or C shape is formed on the top of the post in order to make an electrical contact with the upper multilayer reflection film 27. The ring- or C-shaped upper electrode 29 allows laser light to be emitted from the resultant aperture. The lower electrode 31 is provided on the backside of the substrate 21.

At this stage, the operation of the device can be checked. Current is injected to the device via the top electrode 29 or the bottom electrode 31 so that the oscillation threshold current and maximum optical power of the device can be measured. Based on data thus obtained, the specification of the additional reflection film 30 formed at the following step can be determined.

Then, an ITO layer is formed so as to cover the aperture 29a formed in the upper electrode 29, and subsequently a multilayer film including TiO₂ and SiO₂ layers is deposited. Then, the device is subjected to a liftoff process, so that the additional reflection film 30 can be formed in the center of the substrate and provided on the top of the post. Each of the additional reflection film 30 may be equal to λ/4nᵣ like the lower multilayer reflection film 22. The additional reflection film 30 is provided so as to cover at least part of the light emission region.

As described above, the number of periods with which the TiO₂ layers and the SiO₂ layers are alternately laminated one by one is determined based on data obtained by measuring the oscillation threshold current and the maximum optical output. In this case, TiO₂ has a refractive index of about 2.3 and SiO₂ has a refractive index of about 1.5. Thus, the TiO₂ layer and the SiO₂ layer have a large difference in refractive index, while the additional reflection film is directed to improving the reflectance. Therefore, only one to five periods are enough to obtain the desired function. In the above-mentioned process, the VCSEL according to the second embodiment can be fabricated.

The first embodiment has the intra-cavity structure, and the second embodiment employs the n-side electrode provided on the backside of the substrate. These structures are not associated with the additional reflection film and may be interchanged with each other.

The first embodiment employs the post having a cylindrical shape, while the second embodiment employs the post having a rectangular column shape. These structures are not associated with the additional reflection film, and the shapes of the post are note related to the concept of the additional reflection film. It is therefore possible to select arbitrary shapes of the post.

In the first and second embodiments, the substrate is interposed between the p-side and n-side electrodes in which the p-side electrode is on the further side and the n-side electrode is on the near side. Alternatively, the p-side electrode may be on the near side, and the n-side electrode may be on the further side.

In the first and second embodiments, the oxidizing process is applied to form the current/light confinement layer that may be the AlAs layer or the Al_{0.98}Ga_{0.02}As layer containing a slight amount of gallium. However, the current/light confinement layer may be made of another material that lattice-matches the semiconductor substrate and is oxidized much faster than the peripheral layers.

The current confinement layer is provided above the spacer layer in the first embodiment and below the spacer layer in the second embodiment. However, the position of the current confining layer is not limited to the above but may be selected in terms of workability and performance desired. Preferably, the current confining layer is provided on at least one side of the spacer layer. The current confining layers may be provided on both sides of the spacer layer.

The first embodiment employs the additional reflection film 10 formed by the combination of ITO/ZnO, and the second embodiment employs the additional reflection film 30 formed by the combination of TiO₂/SiO₂ (except ITO layer). However, the present invention is not limited to these combinations. For example, a conductive film of SnO₂ may be used, and a dielectric film of MgO, Al₂O₃ may be used.

The additional reflection film should overlap at least a part of the light emission region in the direction perpendicular to the main surface of the substrate. The additional reflection film may cover the whole emission region, or may cover a part of the center portion or peripheral edge portion of the emission region.

The surface-emitting semiconductor layer device of the present invention may have a single light emission region or multiple light emission regions arranged in a two-dimensional array. The present invention can be used as an optical source of optical communications or recording.

In short, according to an aspect of the present invention, a surface-emitting semiconductor laser comprising a first reflection layer formed on a substrate; an active layer formed on the first reflection layer; a second reflection layer formed on the active region; an electrode that has an aperture that defines a light emission range and is provided on the second reflection layer so that an uppermost layer of the second reflection layer is exposed through the aperture; and a third reflection layer that is provided on the electrode so as to cover the aperture, the third reflection layer including a conductive film that electrically contacts the uppermost layer of the second reflection layer.

According to another aspect of the present invention, there is provided a method of fabricating a surface-emitting semiconductor laser comprising the steps of: forming, on a substrate, a first reflection layer, a second reflection layer, an active region interposed between the first and second reflection layers, and at least one current confining layer interposed between the first and second reflection layers; forming electrodes via which current is injected to the active region; checking an operating characteristic by injecting the current to the active region; and forming, after checking the operation characteristic, an additional reflection layer on the second reflection layer.

According to the present invention, the third reflection layer is provided in addition to the first and second reflection layers between which the active region is interposed. It is thus possible to increase the reflectance of the resonator on the side of light emitting to a desired value. The optical output per injected current may be decreased due to decrease of the slope efficiency. However, the threshold value for oscillation is also reduced. Thus, the response can be improved for an identical magnitude of current injected, as compared to the original reflectance.

The current density does not change greatly. Thus, the lifetime of the device is not affected. An increased reflectance reduces the influence of return light, so that anti-noise performance can be improved.

Although a few preferred embodiments of the present invention have been shown and described, it would be appreciated by those skilled in the art that changes may be made in these embodiments without departing from the principles and spirit of the invention, the scope of which is defined in the claims and their equivalents.

The entire disclosure of Japanese Patent Application No. 2003-393580 filed on Jun. 11, 2003 including the specification, claims, drawings and abstract is incorporated therein by reference in its entity.

1. A surface-emitting semiconductor laser comprising a first reflection layer formed on a substrate;
an active layer formed on the first reflection layer;
a second reflection layer formed on the active region;
an electrode that has an aperture that defines a light emission range and is provided on the second reflection layer so that an uppermost layer of the second reflection layer is exposed through the aperture; and
a third reflection layer that is provided on the electrode so as to cover the aperture,
the third reflection layer including a conductive film that electrically contacts the uppermost layer of the second reflection layer.

2. The surface-emitting semiconductor layer as claimed in claim 1, wherein the third reflection layer includes a laminate of semiconductor layers.

3. The surface-emitting semiconductor laser as claimed in claim 1, wherein the third reflection layer includes a laminate of dielectric layers.

4. The surface-emitting semiconductor laser as claimed in claim 1, wherein one of the first and second reflection layers includes a current confinement layer, which includes an oxidized region around a conductive region.

5. The surface-emitting semiconductor laser as claimed in claim 4, wherein an aperture in an electrode is associated with the conductive region of the current confinement layer and has a size smaller than that of the conductive region.

6. The surface-emitting semiconductor laser as claimed in claim 1, wherein each of the first and second reflection layers has a laminate of AlₓGa₁₋ₓAs layers having different aluminum composition ratios alternately laminated.

7. The surface-emitting semiconductor laser as claimed in claim 1, wherein the third reflection layer has a laminate of indium oxide layers doped with tin (ITO) and zinc oxide layers doped with aluminum (ZnO) alternately laminated.

8. The surface-emitting semiconductor laser as claimed in claim 1, wherein the third reflection layer has a laminate of titanium dioxide (TiO₂) layers and silicon dioxide (SiO₂) layers alternately laminated, and an ITO layer that contacts an uppermost layer of the second reflection layer.

9. The surface-emitting semiconductor laser as claimed in claim 1, wherein a mesa including layers ranging from the second reflection layer to a current confining layer is formed, and an oxidized region of the current confining layer results from oxidizing from a side surface of the mesa.

10. A method of fabricating a surface-emitting semiconductor laser comprising the steps of:
forming, on a substrate, a first reflection layer, a second reflection layer, an active region interposed between the first and second reflection layers, and at least one current confining layer interposed between the first and second reflection layers;
forming electrodes via which current is injected to the active region;
checking an operating characteristic by injecting the current to the active region; and
forming, after checking the operation characteristic, an additional reflection layer on the second reflection layer.

11. The method as claimed in claim 10, wherein the step of checking includes measures an oscillation threshold current of the surface-emitting semiconductor laser.

12. The method as claimed in claim 10, wherein the step of checking includes a step of measuring a maximum optical output.

13. The method as claimed in claim 10, wherein the step pf forming the additional reflection layer determines a number of periods with which layers are laminated to form the additional reflection layer on the basis of data measured obtained at the step of checking.

14. The method as claimed in claim 10, wherein:
the step of forming the electrodes includes a step of forming an electrode having an aperture through which an uppermost layer of the second reflection layer is exposed; and
the step of forming the additional reflection layer includes a step of forming a multilayer reflection film including a conductive layer that electrically contacts the uppermost layer of the second reflection layer.

15. The method as claimed in claim 10, wherein the step of forming the additional reflection layer that includes a laminate of ITO layers and ZnO layers alternately laminated.

16. The method as claimed in claim 10, wherein the step of forming the additional reflection layer that includes a laminate of TiO₂ layers and SiO₂ layers alternately laminated, and an ITO layer that contacts an uppermost layer of the second reflection layer.

17. The method as claimed in claim 10, wherein the step of forming the first and second reflection layers, the active region and said at least one current confining layer includes steps of forming a mesa by etching the layers on the substrate in which a side surface of said at least one current confining layer is exposed and oxidizing a side surface of the mesa so that an oxidized region is formed in the current confining layer.
